(19) United States
(12) Patent Application Publication
(10) Pub. No.: US 2003/0027428 A1
(43) Pub. Date: Feb. 6, 2003

(54) Bypass set up for integration of remote optical endpoint for CVD chamber

(75) Inventors: Wendy Ng, San Jose, CA (US); Toan Tran, San Jose, CA (US); Yen-Kun Victor Wang, Fremont, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/908,822

(22) Filed: Jul. 18, 2001

(51) Int. Cl. H01L 21/302; H01L 21/461

(52) U.S. Cl. 438/706

(57) ABSTRACT

Accumulation of material in an endpoint detection cell downstream of a CVD chamber is avoided by selectively isolating the endpoint detection cell from chamber exhaust. During initial and midpoint phases of a plasma-based semiconductor fabrication process when concentration of materials in the chamber exhaust is heaviest, a bypass valve is closed and the endpoint detection cell is isolated from exposure to exhaust from the chamber. As endpoint of the plasma-based process approaches, the isolation valve is opened and the detection cell is exposed to chamber exhaust and can accurately detect the precise endpoint of the process. By selectively isolating the endpoint detector in accordance with embodiments of the present invention, unwanted accumulation of deposited materials that could degrade reliability of an optical or RF power endpoint detection signal is avoided.

### BACKGROUND OF THE INVENTION

Chemical vapor deposition (CVD) is widely employed in the manufacture of semiconductor devices. A wide variety of materials utilized in integrated circuits, such as polycrystalline and amorphous silicon, dielectric materials, and conducting metals, may be formed by CVD.

As layers of material are repeatedly deposited on substrates present within a CVD chamber, residues accumulate on exposed surfaces of the chamber. In order to avoid contamination of wafers by these residues, it is periodically necessary to remove these residues. Chamber cleaning is typically performed by exposing the interior of the chamber to plasma or excited species generated by a plasma, which in turn reacts with and consumes residual material.

One issue arising from CVD chamber cleaning is determination of the endpoint of the process, when sufficient amounts of residue have been consumed by the plasma and the chamber is clean. Undercleaning the CVD chamber can leave residues in the chamber, giving rise to the possibility of contamination of subsequently-processed wafers. Conversely, overexposure of the CVD chamber to cleaning plasma can damage the chamber, and can also affect process throughput by reducing the availability of the chamber.

One conventional approach for detecting the endpoint of a CVD chamber cleaning process is to monitor optical emissions from a plasma cell located downstream of the chamber. However, materials consumed by the plasma in the chamber during the cleaning process can later be redeposited on exposed surfaces of the plasma cell, affecting the consistency and reliability of endpoint detection.

Accordingly, a need exists for an accurate method and apparatus for monitoring endpoint of a cleaning step for a CVD chamber.

### SUMMARY OF THE INVENTION

Unwanted accumulation of material in an endpoint detection cell downstream of a CVD chamber is avoided by selectively isolating the detection cell from chamber exhaust. During CVD and initial chamber cleaning phases, a bypass valve is closed and the endpoint detection cell is isolated from exposure to exhaust from the chamber. As endpoint of the plasma based cleaning process approaches, the isolation valve is opened and the detection cell is exposed to exhaust from the chamber, permitting accurate detection of the precise chamber clean endpoint. By selectively isolating the endpoint detector in accordance with embodiments of the present invention, unwanted accumulation of materials in the endpoint detector that can degrade the accuracy of endpoint detection is avoided.

An embodiment of an apparatus for detecting endpoint of a CVD process comprises a processing chamber configured to receive an excited species from a plasma source, the processing chamber including a throttle valve configured to output an exhaust from the processing chamber. A bypass foreline is positioned downstream from the throttle valve, the bypass foreline including an isolation valve. An endpoint detection cell is positioned downstream from the isolation valve and selectively isolated from exposure to chamber exhaust by the isolation valve.

An embodiment of a method for detecting endpoint of a CVD process comprises providing an endpoint detector, isolating the endpoint detector from exposure to an exhaust of a plasma based semiconductor fabrication process during an initial stage of the process, and exposing the endpoint detector to exhaust from the process during a later stage of the process.

An embodiment of a method of operating a substrate processing chamber having an endpoint detection cell in fluid communication with an exhaust line of the processing chamber comprises transferring a substrate into the substrate processing chamber, processing the substrate in the chamber such that deposits form on an interior chamber surface, and transferring the substrate from the chamber. The deposits are etched through exposure to an excited species, and the etched byproducts are exhausted from the chamber through the exhaust. An endpoint of the etching using the endpoint detection cell is identified, such that endpoint detection cell is isolated from the exhaust line during a first portion of the etching, and during a second portion of the etching the endpoint detection cell is exposed to the etch byproducts.

These and other embodiments of the present invention, as well as its advantages and features, are described in more detail in conjunction with the text below and attached figures.

### BRIEF DESCRIPTION OF THE DRAWINGS

FIG. 1 is a vertical, cross-sectional view of one embodiment of a simplified high density chemical vapor deposition apparatus according to the present invention.

FIG. 2 plots voltage versus time for a conventional chamber cleaning process.

FIG. 3 is a simplified schematic view of a CVD apparatus in accordance with one embodiment of the present invention.

FIG. 3A is a flow chart showing a series of method steps of one embodiment for determining endpoint of a chamber cleaning process in accordance with the present invention.

FIG. 4 is an enlarged view of an alternative embodiment of a bypass foreline structure in accordance with the present invention.

FIGS. 5A and 5B show photographs of upstream and downstream sides, respectively, of an endpoint electrode positioned proximate to the throttle valve of a CVD chamber.

FIGS. 6A and 6B show photographs of upstream and downstream sides, respectively, of an endpoint electrode positioned six inches downstream from the throttle valve of a CVD chamber.

FIGS. 7A-7C show photographs of upstream and downstream sides, respectively, of an endpoint electrode positioned forty inches downstream from the throttle valve of a CVD chamber.

FIGS. 8A and 8B, and FIGS. 9A and 9B, show photographs of upstream and downstream sides, respectively, of an endpoint electrode positioned in a bypass foreline structure in accordance with one embodiment of the present invention.

### DESCRIPTION OF THE SPECIFIC EMBODIMENTS

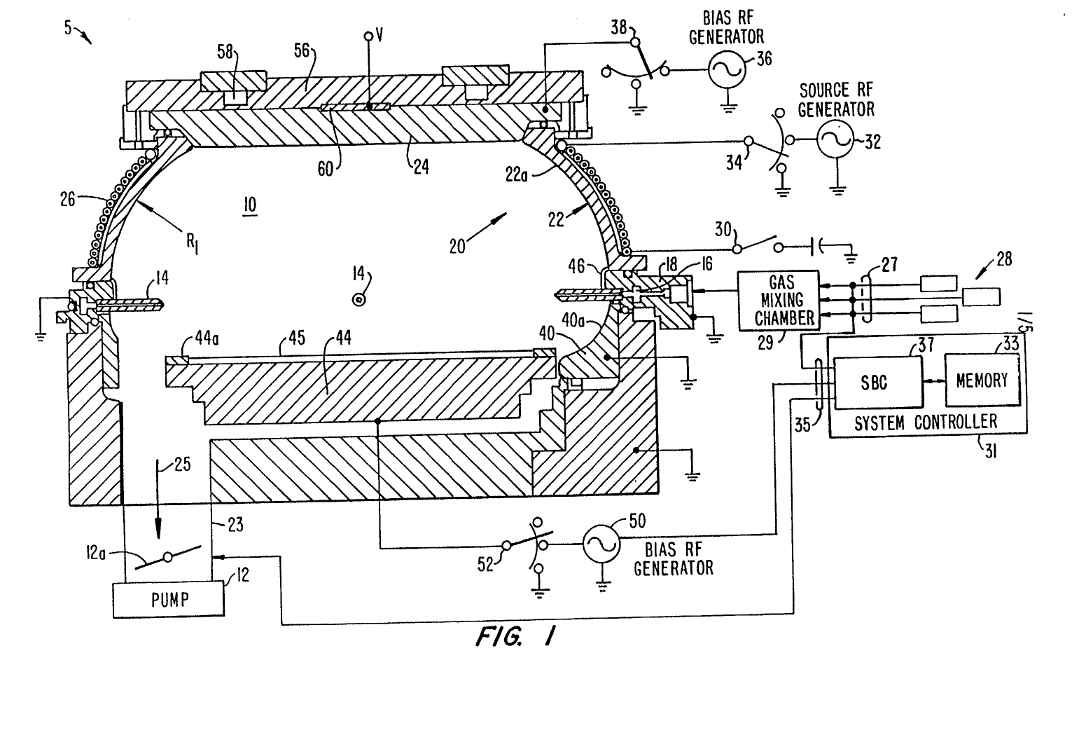

FIG. 1 illustrates one embodiment of a high density plasma (HDP) CVD system 5 in which endpoint can be detected according to the present invention. HDP-CVD system 5 includes a vacuum chamber 10, a vacuum pump 12, a bias RF (BRF) generator 36, and a source RF (SRF) generator 32.

Vacuum chamber 10 includes a ceiling 11 consisting of a sidewall 22 and a disk-shaped ceiling electrode 24. Sidewall 22 is made of an insulator such as quartz or ceramic and supports coiled antenna 26.

Deposition gases and liquids are supplied from gas sources 28 through lines 27, having control valves not shown, into a gas mixing chamber 29 where they are combined and sent to gas supply ring manifold 16. Generally, each gas supply line for each process gas includes (i) safety shut-off valves (not shown) that can be used to automatically or manually shut off the flow of process gas into the chamber, and (ii) mass flow controllers (MFCs) (also not shown) that measure the flow of gas through the gas supply lines. When toxic gases are used in the process, the several safety shut-off valves are positioned on each gas supply line in conventional configurations.

Gas injection nozzles 14 are coupled to gas supply ring manifold 16 and disperse deposition gases introduced into manifold 16 to a substrate 45 resting on a pedestal 44 within chamber 10. Additionally, a center gas injection nozzle (not shown) and a center annulus (not shown) admit gases to chamber 10 above substrate 45. Deposition gases introduced through gas injection nozzles 14, center gas injection nozzle, and center annulus may be of the same or different compositions. Pedestal 44 may be moved up and down by a motor (not shown) into various processing positions. Additionally, pedestal 44 may contain an electrostatic chuck or similar mechanism to restrain the wafer during processing and may also contain cooling passages and other features.

Gas supply ring manifold 16 is positioned within a housing 18. Housing 18 is protected from reagents by a skirt 46. Skirt 46 is composed of a substance, such as quartz, ceramic, silicon or polysilicon, which is resistant to the reagents used in the HDP-CVD process. The bottom of vacuum chamber 10 may include an annular liner 40, which itself may be made removable.

An inductively coupled plasma of the deposition gases can be formed adjacent to substrate 45 by RF energy applied to coiled antenna 26 from source RF generator 32. Source RF generator 32 can supply either single or mixed frequency RF power (or other desired variation) to coiled antenna 26 to enhance the decomposition of reactive species introduced into vacuum chamber 10. A plasma formed in such a manner has a relatively high density (on the order of 10¹¹ to 10¹² ions/cm³) as compared with standard PECVD reactors. Deposition gases are exhausted from chamber 10 through exhaust line 23 as indicated by arrow 25. The rate at which gases are released through exhaust line 23 is controlled by throttle valve 12a.

Ceiling electrode 24 is held in place by a lid 56, which is cooled by cooling jackets 58. Ceiling electrode 24 is a conductor and may be connected to either ground, to a BRF generator 36, or left unconnected (allowed to float), by properly setting switch 38. Similarly, pedestal 44 may be connected to either ground, to a BRF generator 50 or left unconnected (allowed to float), by properly setting switch 52. The settings of these switches depends upon the plasma's desired characteristics. BRF generators 36 and 50 can supply either single or mixed frequency RF power (or other desired variation). BRF generators 36 and 50 may be separate RF generators, or may be a single RF generator connected to both ceiling electrode 24 and pedestal 44. Application of RF energy from BRF generators 36 and 50 to bias an inductively coupled plasma toward pedestal 44 promotes sputtering and enhances existing sputtering effects of the plasma (i.e., increasing the gap-fill capability of a film).

Capacitive coupling may also be used to form the plasma. Such a plasma may be formed between ceiling electrode 24 and pedestal 44 or in a similar fashion.

BRF generators 36 and 50, SRF generator 32, throttle valve 12a, the MFCs connected to lines 27, switches 30, 34, 38 and 52, and other elements in CVD system 5 are all controlled by a system controller 31 over control lines 35, only some of which are shown. System controller 31 operates under the control of a computer program stored in a computer-readable medium such as a memory 33, which, in the preferred embodiment is a hard disk drive. The computer program dictates the timing, introduction rate and mixture of gases, chamber pressure, chamber temperature, RF power levels and other parameters of a particular process. Motors and optical sensors are used to move and determine the position of movable mechanical assemblies such as throttle valve 12a and pedestal 44.

System controller 31 controls all of the activities of the CVD apparatus. In a preferred embodiment, controller 31 includes a hard disk drive (memory 33), a floppy disk drive, and a card rack. The card rack contains a single board computer (SBC) 37, analog and digital input/output boards, interface boards and stepper motor controller boards (only some of which are shown). The system controller conforms to the Versa Modular European (VME) standard which defines board, card cage, and connector dimensions and types. The VME also defines the bus structure having a 16-bit data bus and 24-bit address bus.

The above description is for illustrative purposes only and should not be considered as limiting the scope of the present invention. Variations of the above-described system, such as variations in pedestal design, chamber design, location of RF power connections and other variations are possible. Additionally, other systems such as electron cyclotron resonance (ECR) plasma CVD devices, thermal CVD devices, PECVD systems, sputtering systems or the like, can enjoy the benefits of the present invention. The method and apparatus of the present invention are not limited to any specific substrate processing system

Conventionally, an endpoint detection apparatus is positioned in the chamber exhaust line directly downstream of the throttle valve. Such an endpoint detection cell may comprise a cathode positioned with a space defined by cell walls that serve as an anode. Application of a potential difference between the cathode and the cell walls triggers an electrical discharge. The character of light resulting from interaction between the electrical discharge and gases present in the endpoint detection apparatus can be detected to measure endpoint.

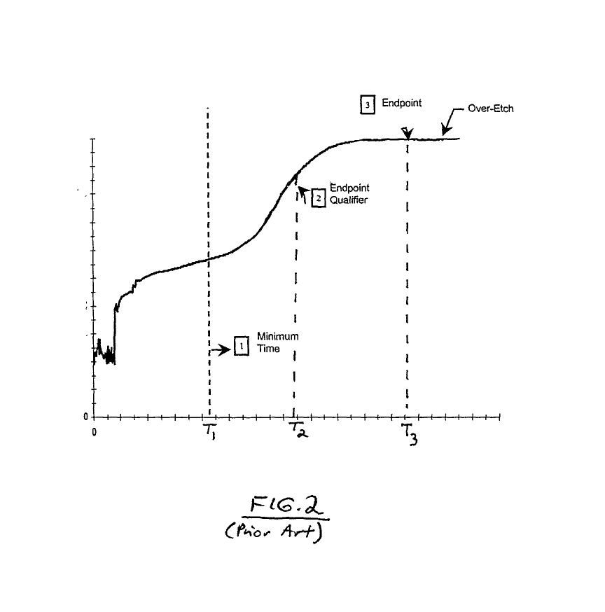

FIG. 2 plots a voltage vs. time profile for a conventional chamber cleaning process, where voltage is output from an optical sensing device such as a photodiode or phototransistor. FIG. 2 shows an initial large fluctuation in voltage, and after a minimum time T₁ the time/voltage relationship assumes a first linear profile having a first slope.

At time T₂, the slope of the curve changes to indicate a decline in the rate of change of voltage over time. This change is an endpoint qualifier, indicating the approach of endpoint of the chamber clean process. At time T₃, endpoint of the cleaning process is indicated, as voltage is unchanged with time. Exposure of the chamber to plasma after time T₃ would represent unnecessary overcleaning. The voltage/time relationship shown in FIG. 2 varies for each particular cleaning process, but endpoint is typically presaged by a definable endpoint qualifier. This endpoint qualifier may be determined experimentally for a particular process, and then correlated to a specific elapsed time of the process, or to other indicia such as temperature.

Conventional endpoint detection apparatuses may be subject to inaccuracy due to the unwanted build-up of materials on exposed surfaces. For example, deposition of material on the cathode and on the walls of the plasma cell can affect the strength of the electrical discharge, and hence the stability and intensity of the optical signal from the plasma. Variation in the detected optical signal can in turn adversely affect the accuracy of endpoint detection.

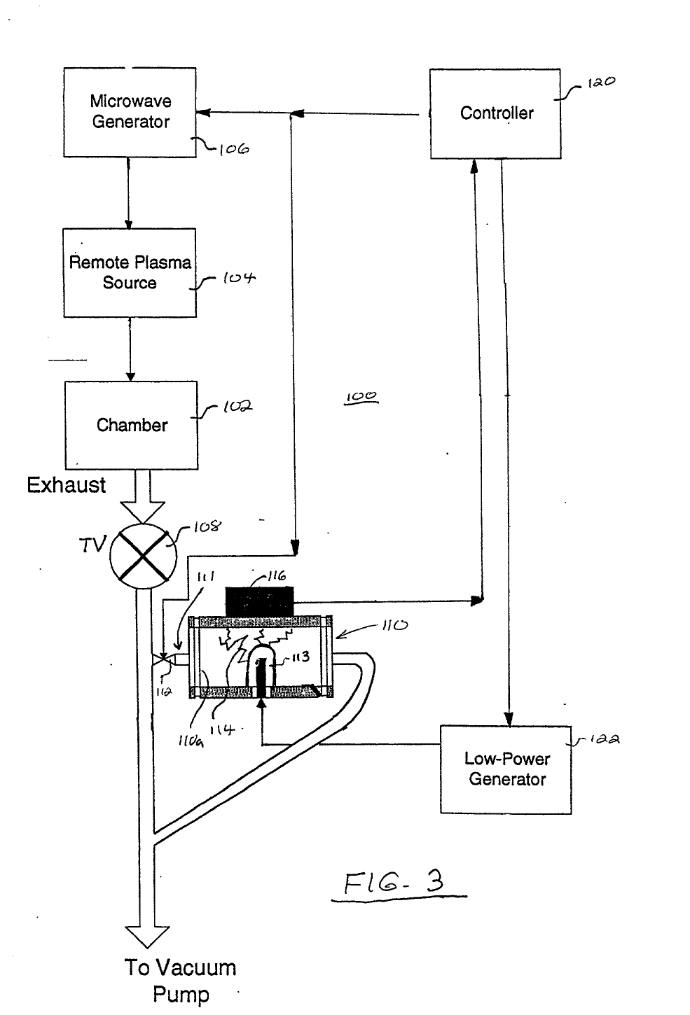

Accordingly, FIG. 3 shows a simplified schematic view of a CVD apparatus including an endpoint detection feature in accordance with one embodiment of the present invention. CVD apparatus 100 includes deposition chamber 102 in communication with remote plasma source 104 that is in turn in communication with microwave generator 106. Gases are exhaust from deposition chamber 102 through throttle valve 108.

Endpoint detection cell 110 is positioned in bypass foreline structure 111. Isolation valve 112 is part of bypass foreline structure 111, and is actuatable to selectively isolate endpoint detection cell 110 from chamber exhaust.

Endpoint detection cell 110 comprises cathode 113 positioned within walls 110a of cell 110. Walls 110a are made from an electrically conductive material such as aluminum, and serve as an anode. Application of a potential difference between cathode 113 and walls 110a triggers electrical discharge 114. The characteristics of light resulting from interaction between electrical discharge 114 and gases present in cell 110 are detected by optical sensor 116. These detected characteristics can include spectral intensity.

Endpoint detector 110 in accordance with one embodiment of the present invention is not positioned directly downstream of throttle valve 108 of CVD chamber 102. Instead, endpoint detector 110 is positioned in bypass foreline structure 111 and is selectively isolatable from throttle valve 108 by isolation valve 112.

Controller 120 is in electrical communication with microwave generator 106, low power generator 122, isolation valve 112, and optical sensor 116. A flowchart illustrating method steps for endpoint detection in accordance with an embodiment of the present invention is shown in FIG. 3A.

In first step 180, CVD apparatus, 100 of FIG. 3 deposits a layer of material on a substrate present within chamber 102, and then the substrate is removed from the chamber. In second step 182, controller 120 of FIG. 3 communicates a signal to microwave generator 106 to initiate a chamber cleaning process.

In third step 184, plasma is generated in remote plasma source 104 of FIG. 3, typically by the exposure of fluorine-containing gases such as NF₃ to microwave energy. In fourth step 186, reactant species from the plasma is flowed into deposition chamber 102 to react with and consume residues present on the walls and other surfaces of chamber 102. In fifth step 188, gaseous by-products of this cleaning reaction are flowed out of chamber 102 through throttle valve 108 to a vacuum pump.

During initial and midpoint stages of the chamber cleaning process, isolation valve 112 is closed by controller 120 to ensure that the flow of chamber exhaust through throttle valve 108 does not reach endpoint detection apparatus 110. As illustrated below, this is beneficial because effluent from the chamber during early and intermediate cleaning stages may contain high concentrations of materials that could reform on exposed surfaces of endpoint detection apparatus 110, degrading the accuracy of endpoint detection.

In sixth step 190, approach of the endpoint of the chamber cleaning process is identified by an endpoint qualifier, based for example on a predetermined elapsed time of the chamber cleaning process. The endpoint qualifier would typically be determined empirically for a specific tool based upon previous deposition of material according to a particular recipe, such that occurrence of the endpoint qualifier, and the approach of chamber cleaning endpoint, could be predicted with confidence without having to rely upon the endpoint detector. For example, optical emissions from a non-isolated endpoint detection cell could be monitored from the commencement of prior CVD chamber cleaning runs in order to identify an average elapsed time for endpoint qualifier.

As process endpoint approaches, controller 120 communicates a signal opening isolation valve 112, thereby permitting exhaust from chamber 102 to flow through isolation valve 112 and endpoint detection apparatus 110. Controller 120 causes low power generator 122 to supply constant power to cathode 113. The resulting electrical discharge 114 between cathode 113 and plasma cell walls 110a serving as the anode creates a characteristic optical signal. The nature of the optical signal is dependent upon the environment within endpoint detection cell 110.

Specifically, a constant low power is supplied to cathode 113 from low power generator 122. As residues are removed from CVD chamber 102 and the chamber effluent contains less material, in seventh step 192 stabilization in detected optical emissions reveals the endpoint of the chamber cleaning process.

FIG. 4 shows an enlarged view of an alternative embodiment of a bypass foreline 150 in accordance with the present invention. Bypass foreline 150 includes isolation valve 152, and differs slightly in shape from the bypass foreline depicted in FIG. 3.

In order to assess the effectiveness of a bypass foreline structure in accordance with an embodiment of the present invention, a series of experiments were conducted. Specifically, a number of wafers were processed in an Applied Materials Model 2358C SACVD Gigafill Chamber under the following conditions:

Deposition time=305 sec;

Deposition temperature=570° C.;

Deposition pressure=700 Torr;

Gap between shower head and wafer=200 mm;

O₃ flow rate=5,000 cm³/s;

N₂ flow rate=10,000 cm³/s;

TEOS flow rate=1,300 mg/min.

After each wafer was processed under these conditions, the chamber was subjected to a plasma cleaning step under the following conditions:

Cleaning temperature=570° C.;

Cleaning pressure=1.5 Torr;

Gap between shower head and wafer=550 mm;

Applied microwave power=2,100 Mw; and

NF₃ cleaning gas flow rate=950 cm³/s.

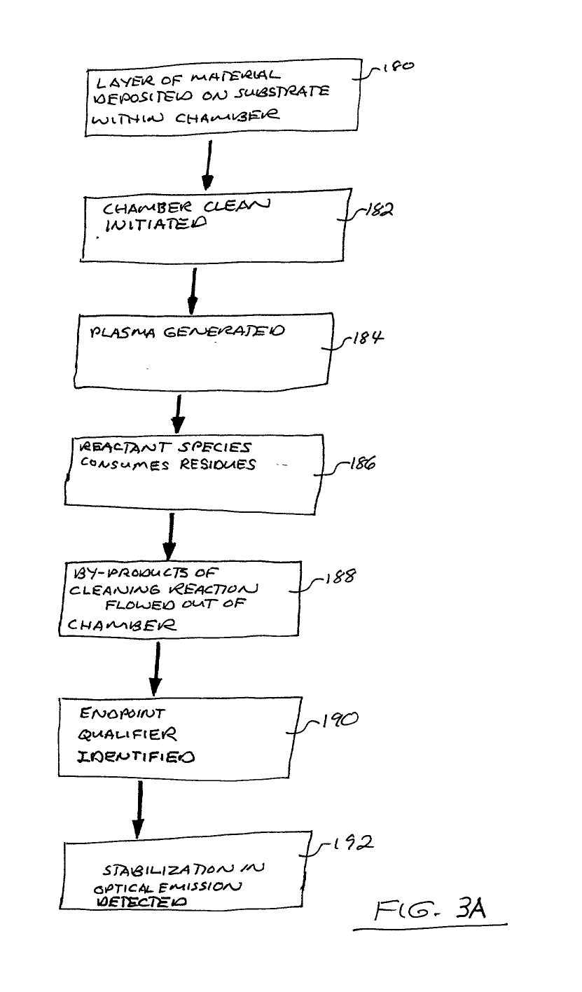

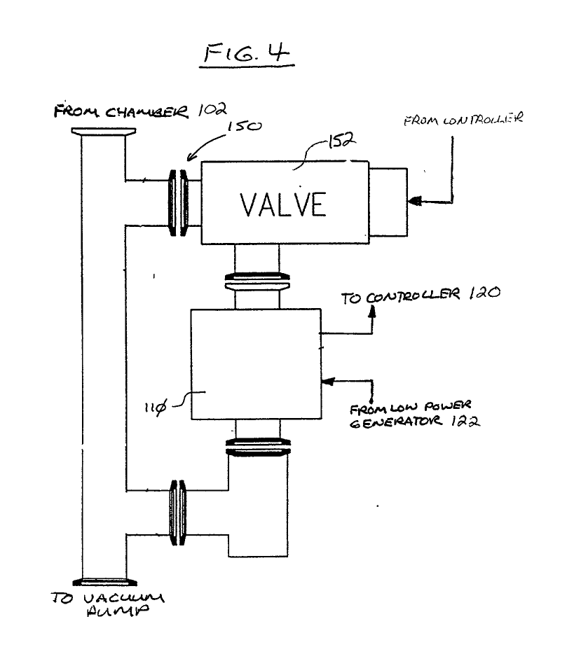

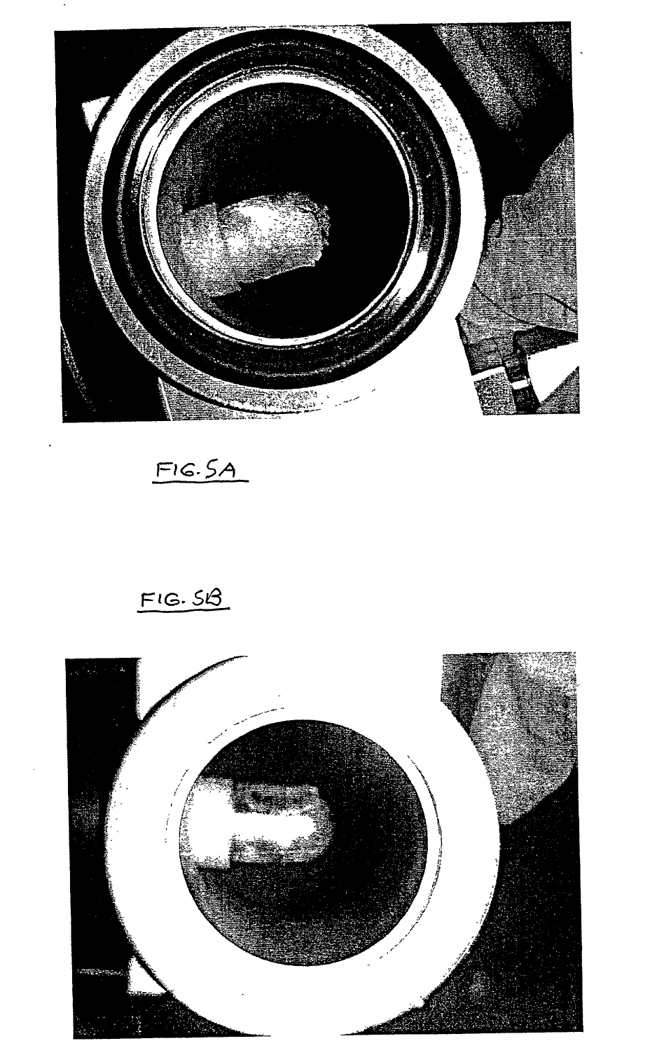

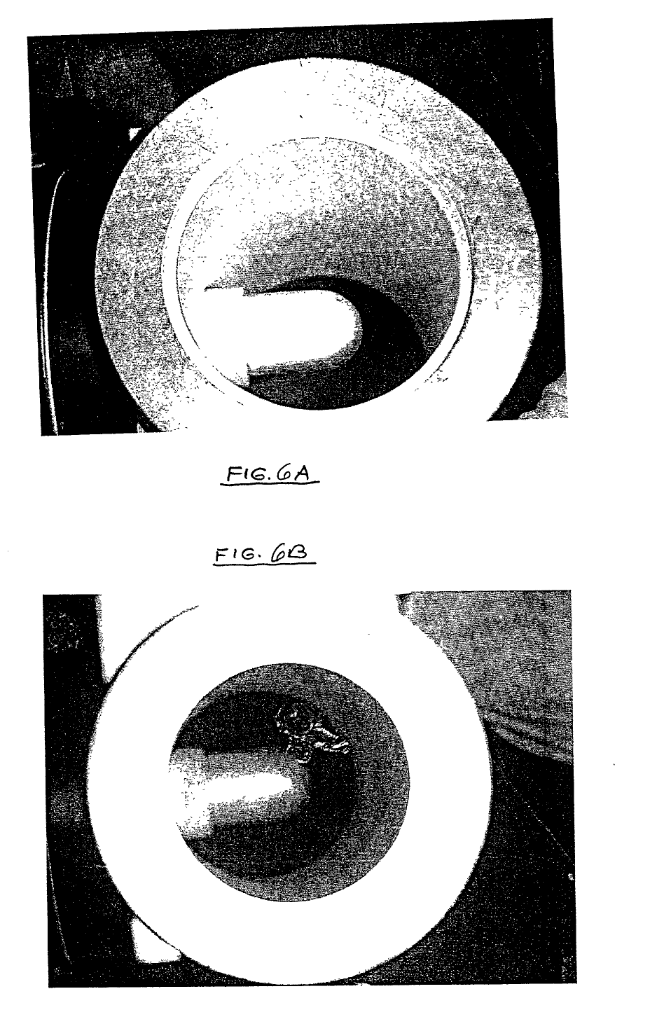

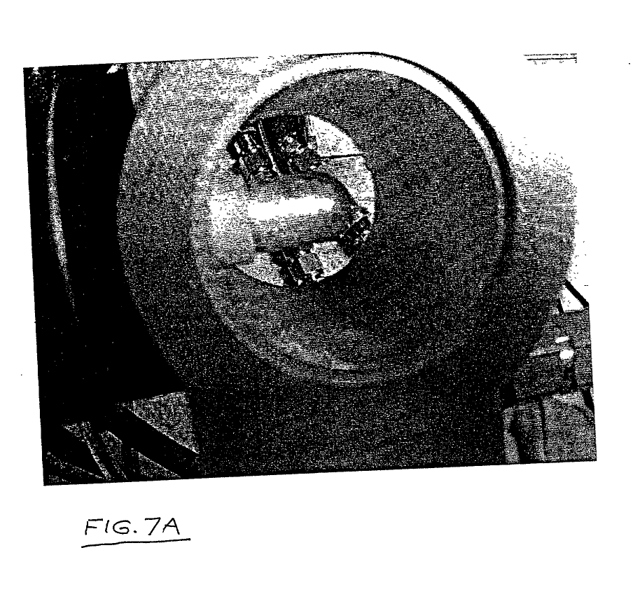

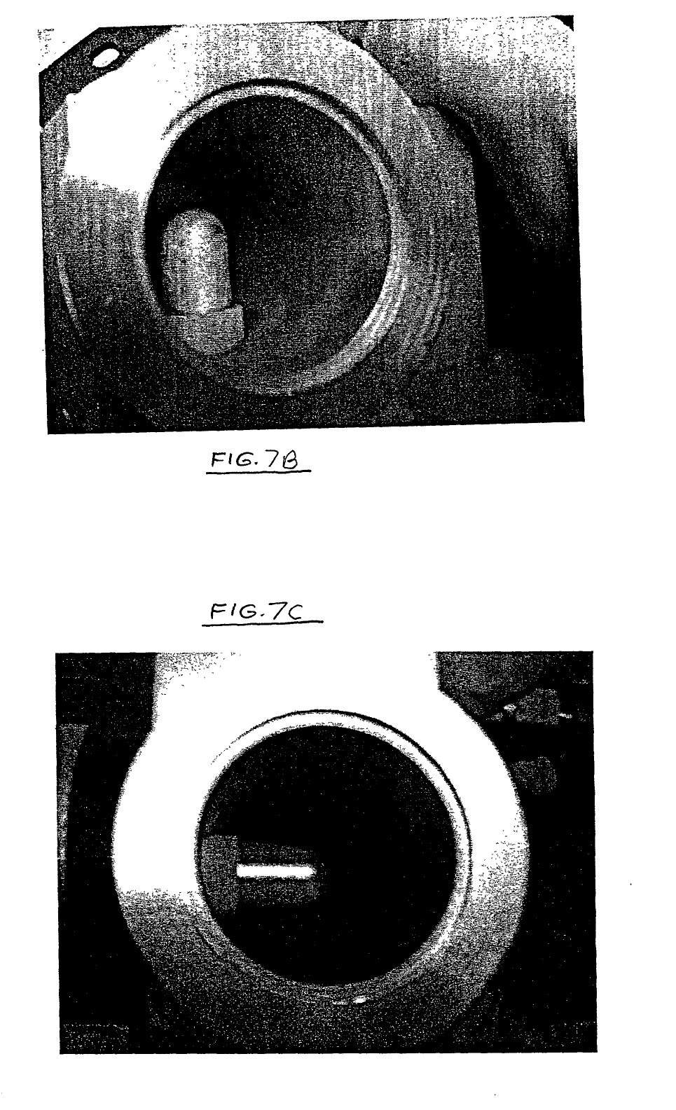

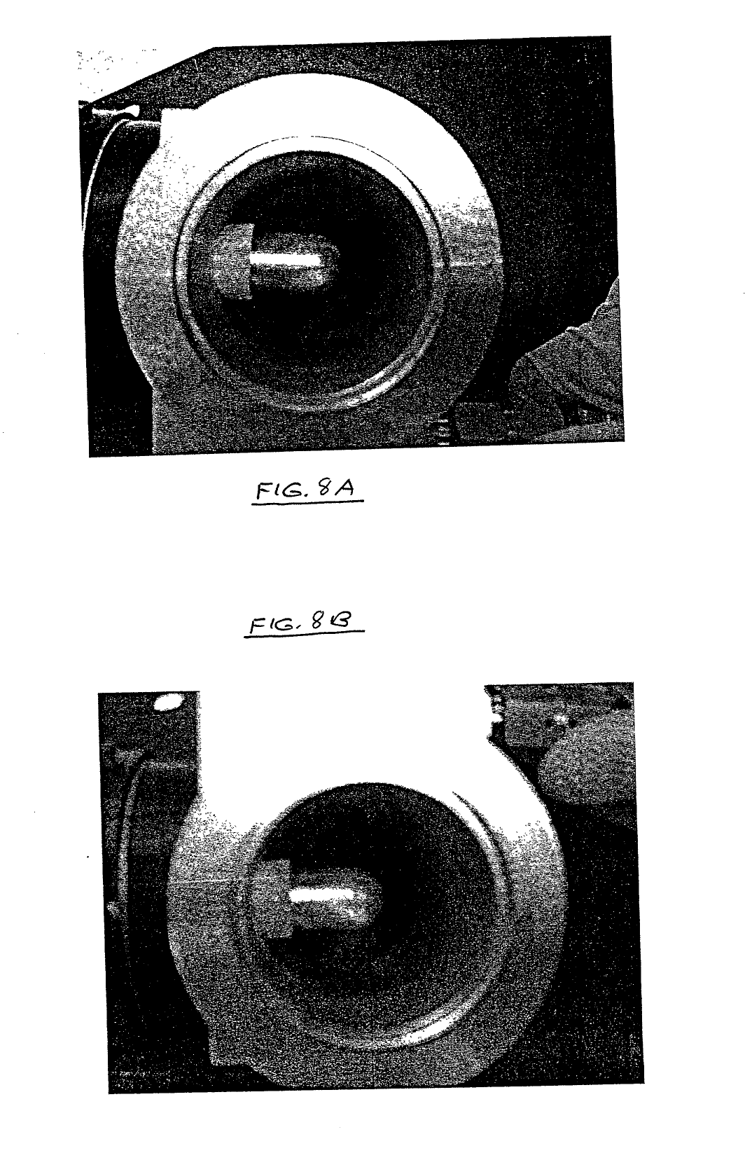

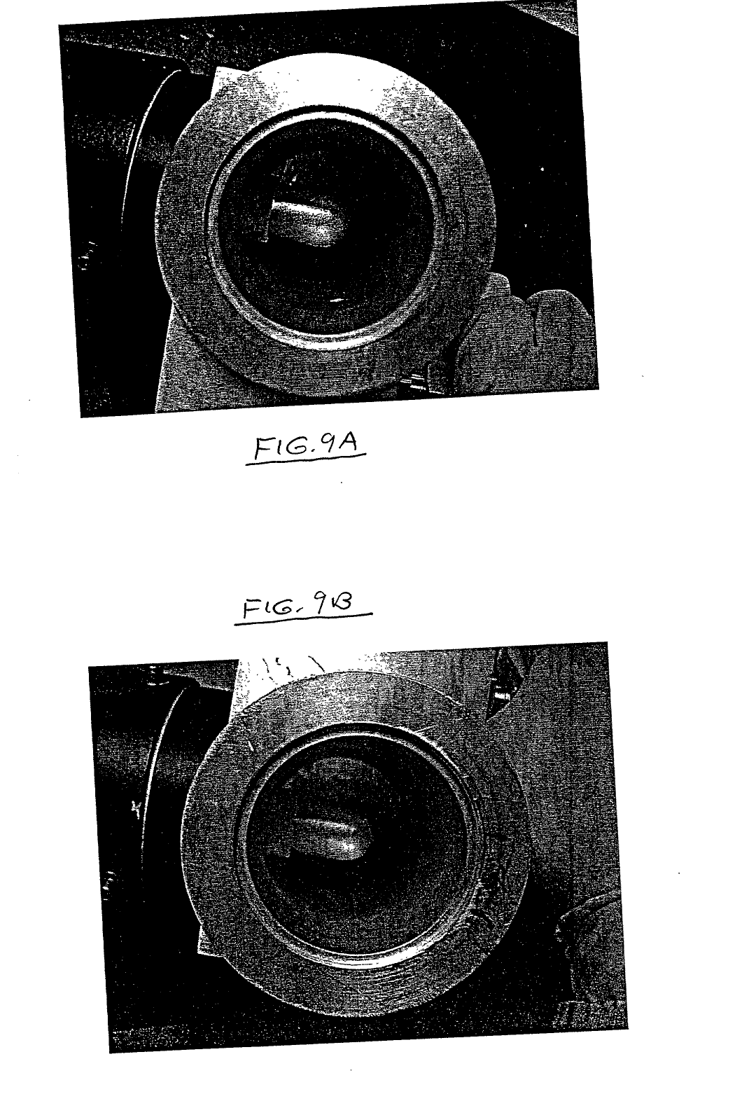

Photographs were then taken of the plasma cell cathode in a number of configurations. These photographs shown in FIGS. 5A-9B, and are summarized below in TABLE 1.

TABLE 1

| | No. of | | | |
|---|---|---|---|---|
| | Consecutive | | | |
| | Deposition/Clean | Location of | Side of | |
| FIG. | Cycles Prior | Endpoint | Cathode | Deposition |
| No. | to Photo | Detector | Shown | on Cathode |
| 5A | 220 | proximate to | up- | heavy coating of |
| | | throttle valve | stream | material |
| 5B | 220 | proximate to | down- | heavy coating of |
| | | throttle valve | stream | material |
| 6A | 95 | 6″ downstream | up- | medium coating |
| | | from throttle | stream | of material |
| | | valve | | |
| 6B | 95 | 6″ downstream | down- | medium coating |
| | | from throttle | stream | of material |
| | | valve | | |
| 7A | 100 | 40″ downstream | up- | thin layer of |
| | | from throttle | stream | powder on |
| | | valve | | upstream side, no |
| | | | | powder on |
| | | | | downstream side |
| 7B | 220 | 40″ downstream | up- | 3x the amount of |
| | | from throttle | stream | powder as in FIG. |
| | | valve | | 6A; powder |
| | | | | migrating to side |
| | | | | of cathode |
| 7C | 220 | 40″ downstream | down- | no white powder |
| | | from throttle | stream | on downstream |
| | | valve | | side |
| 8A | 230 | bypass foreline | up- | no white powder |
| | | | stream | on cathode |
| 8B | 230 | bypass foreline | down- | no white powder |
| | | | stream | on cathode |
| 9A | 900 | bypass foreline | up- | minimal amounts |
| | | | stream | of white powder |
| | | | | on cathode |
| 9B | 900 | bypass foreline | down- | minimal amounts |
| | | | stream | of white powder |
| | | | | on cathode |

The experimental results shown in FIGS. 5A-9B and summarized in TABLE 1 indicate that selective isolation of the endpoint detector cathode in a bypass foreline is effective in reducing unwanted accumulation of materials on the cathode. Moreover, with the bypass design, the endpoint module may accurately detect cleaning endpoint after more than 1000 consecutive deposition/clean steps. Without the bypass design, the endpoint module can continue to accurately detect endpoint after about only 100 consecutive deposition/clean steps.

The above discussion describes only one particular embodiment of a system in accordance wit the present invention. Other equivalent or alternative structures and methods for endpoint detection according to the present invention will be apparent to those skilled in the art.

For example, while the embodiment of the present invention described above may be utilized to detect endpoint of a chamber cleaning process utilizing plasma generated from a remote source and then injected into the chamber, the present invention is not limited to this particular application. Endpoint of a cleaning process utilizing plasma generated directly in the chamber can also be accurately detected utilizing apparatuses and methods in accordance with embodiments of the present invention.

Moreover, while the embodiment of the present invention described above is employed to detect endpoint in a cleaning process for a CVD chamber, the present invention is not limited to this particular application and could be utilized in other plasma-based processes. An endpoint detection cell could be isolated from a plasma etching tool using a bypass foreline, and the resulting method and apparatus would fall within the scope of the present invention.

Similarly, embodiments in accordance with the present invention could also be utilized to detect endpoint in an actual CVD process. In such an application, the isolation valve would be closed during periods of heavy deposition of material at initial and midpoint stages of the process, and then opened as the expected deposition endpoint approaches.

The present invention is also not limited to shielding a particular type of endpoint detector from chamber exhaust. In addition to optical endpoint detection methods, process endpoint may also be detected by monitoring changes in RF power of a plasma cell positioned downstream of the chamber. Specifically, the RF power of plasma in such a downstream detection cell will fluctuate depending upon the concentration and/or composition of gases present in the cell. Shielding such an RF power endpoint detector from chamber exhaust during initial phases of a plasma based process will prevent unwanted deposition of materials, further enhancing accuracy and reliability of endpoint detection.

Given the above detailed description of the present invention and the variety of embodiments described therein, these equivalents and alternatives along with the understood obvious changes and modifications are intended to be included within

What is claimed is:

1. An apparatus for detecting endpoint of a plasma-based semiconductor fabrication process, the apparatus comprising:
a processing chamber configured to receive an excited species from a plasma source, the processing chamber including a throttle valve configured to output an exhaust from the processing chamber;
a bypass foreline positioned downstream from the throttle valve, the bypass foreline including an isolation valve; and
an endpoint detection cell, the endpoint detection cell positioned downstream from the isolation valve and selectively isolated from exposure to chamber exhaust by the isolation valve.

2. The apparatus of claim 1 wherein the endpoint detection cell further comprises a cathode, an anode, and an optical detector, the optical detector detecting an optical signal resulting from an electrical discharge between the cathode and the anode.

3. The apparatus of claim I wherein the endpoint detection cell further comprises a cathode, an anode, and an RF power detector, the RF power detector detecting an RF power of a plasma generated in the endpoint detection cell.

4. The apparatus of claim 1 wherein the processing chamber is one of a plasma-enhanced chemical vapor deposition (PECVD) chamber and a high density plasma chemical vapor deposition (HDP-CVD) chamber.

5. The apparatus of claim 1 wherein the isolation valve is controlled by a controller, the controller programmed to open the isolation valve after an initial phase of the plasma based process.

6. A method of detecting an endpoint of a plasma based semiconductor fabrication process, the method comprising:
providing an endpoint detector;
isolating the endpoint detector from exposure to an exhaust of a plasma based semiconductor fabrication process during an initial stage of the process; and
exposing the endpoint detector to exhaust from the process during a later stage of the process.

7. The method of claim 6 wherein the plasma based semiconductor fabrication process is a chamber cleaning process.

8. The method of claim 6 wherein the plasma based semiconductor fabrication process is one of a plasma enhanced chemical vapor deposition (PECVD) process and a high density plasma chemical vapor deposition (HDP-CVD) process.

9. The method of claim 6 wherein the plasma based semiconductor fabrication process is a plasma etching process.

10. The method of claim 6 wherein isolation of the endpoint detector reduces unwanted deposition of material on exposed surfaces of the endpoint detector, thereby improving a stability of an optical signal produced from an electrical discharge between a cathode and an anode of the endpoint detector.

11. The method of claim 6 wherein isolation of the endpoint detector reduces unwanted deposition of material on exposed surfaces of the endpoint detector, thereby improving a stability of an RF power signal of a plasma generated in the endpoint detector.

12. The method of claim 6 wherein the endpoint detector is exposed after a predetermined elapsed time of the process corresponding to an endpoint qualifier.

13. A method of operating a substrate processing chamber having an endpoint detection cell in fluid communication with an exhaust line of the processing chamber, the method comprising:
transferring a substrate into the substrate processing chamber;
processing the substrate in the chamber such that deposits form on an interior chamber surface;
transferring the substrate from the chamber;
etching the deposits through exposure to an excited species;
exhausting etched byproducts from the chamber through the exhaust; and
identifying an endpoint of the etching using the endpoint detection cell, such that endpoint detection cell is isolated from the exhaust line during a first portion of the etching, and during a second portion of the etching the endpoint detection cell is exposed to the etch byproducts.

14. The method of claim 13 wherein isolation of the endpoint detection cell reduces unwanted deposition of material on exposed surfaces of the endpoint detection cell, thereby improving a stability of an optical signal produced from an electrical discharge between a cathode and an anode of the endpoint detector.

15. The method of claim 13 wherein isolation of the endpoint detection cell reduces unwanted deposition of material on exposed surfaces of the endpoint detection cell, thereby improving a stability of an RF power signal of a plasma generated in the endpoint detection cell.

16. The method of claim 13 wherein the second portion occurs after a predetermined elapsed time of the etching corresponding to an endpoint qualifier.
